(19) United States
(12) Patent Application Publication
(10) Pub. No.: US 2026/0129745 A1
(43) Pub. Date: May 7, 2026

(54) CIRCUIT BOARD STRUCTURE AND MANUFACTURING METHOD THEREOF

(71) Applicant: UNIMICRON TECHNOLOGY CORP., Taoyuan City (TW)

(72) Inventors: Ching-Sheng CHEN, Taoyuan City (TW); Chi-Min CHANG, Taoyuan City (TW); Wei-Yu LIAO, Taoyuan City (TW); Chun-Jui HUANG, Taoyuan City (TW); Yi-Pen LIN, Taoyuan City (TW)

(73) Assignee: UNIMICRON TECHNOLOGY CORP., Taoyuan City (TW)

(21) Appl. No.: 18/968,865

(22) Filed: Dec. 4, 2024

(30) Foreign Application Priority Data
Nov. 4, 2024 (TW) 113142170

(51) Int. Cl. H05K 1/02; H05K 1/03; H05K 3/46

(52) U.S. Cl. CPC H05K 1/025; H05K 1/0313; H05K 3/4644; H05K 2201/0191

(57) ABSTRACT

A circuit board structure and a manufacturing method thereof are provided. The circuit board structure includes a base layer, a first circuit layer, a support material layer, a build-up material layer, and a second circuit layer. The first circuit layer is disposed on the base layer. The support material layer is disposed on the base layer and on one side of the first circuit layer. The build-up material layer is disposed on the first circuit layer and the support material layer. The second circuit layer is disposed on the build-up material layer.

### CROSS REFERENCE TO RELATED APPLICATIONS

This Application claims priority of Taiwan Patent Application No. 113142170, filed on Nov. 4, 2024, the entirety of which is incorporated by reference herein.

### BACKGROUND OF THE INVENTION

### Field of the Invention

The present disclosure relates to a circuit board structure and, in particular, to a circuit board structure in which a support material layer is disposed between a build-up material layer and a base layer and a manufacturing method of the circuit board structure.

### Description of the Related Art

As the application of electronic products becomes more widespread, electronic products are required to have higher performance. For example, in order to meet high-frequency applications, circuit board structures in electronic products need to have better impedance matching and signal integrity. However, some defects in the circuit board structures may lead to poor impedance matching and signal integrity. These defects include uneven thickness and material mismatch, among others. Therefore, although existing circuit board structures have largely met their intended purposes, they do not meet requirements in all respects. Therefore, there is still a need to develop new circuit board structures and manufacturing methods thereof.

### BRIEF SUMMARY OF THE INVENTION

In some embodiments of the present disclosure, a circuit board structure is provided. The circuit board structure includes a base layer, a first circuit layer, a support material layer, a build-up material layer, and a second circuit layer. The first circuit layer is disposed on the base layer. The support material layer is disposed on the base layer and on one side of the first circuit layer. The build-up material layer is disposed on the first circuit layer and the support material layer. The second circuit layer is disposed on the build-up material layer.

In some embodiments of the present disclosure, the base layer includes a first region and a second region, and the ratio of the area of the first circuit layer located on the first region to the total area of the first region is less than the ratio of the area of the first circuit layer located on the second region to the total area of the second region, wherein the support material layer is located at least in the first region.

In some embodiments of the present disclosure, the ratio of the area of the first circuit layer located on the first region to the total area of the first region is less than 50%.

In some embodiments of the present disclosure, the upper surface of the first circuit layer and the upper surface of the support material layer are coplanar.

In some embodiments of the present disclosure, the upper surface of the build-up material layer located on the support material layer and the upper surface of the build-up material layer located on the first circuit layer are coplanar.

In some embodiments of the present disclosure, the material of the support material layer includes epoxy, silicon dioxide, bisphenol F, epichlorhydrin, a copolymer thereof, or a combination thereof.

In some embodiments of the present disclosure, the material of the support material layer is the same as the material of the build-up material layer.

In some embodiments of the present disclosure, the thickness of the support material layer is between 0.01 mm and 0.12 mm.

In some embodiments of the present disclosure, the support material layer is not in direct contact with the first circuit layer.

In some embodiments of the present disclosure, the shortest distance between the support material layer and the first circuit layer is greater than 0.03 mm.

In some embodiments of the present disclosure, the build-up material layer is located between the support material layer and the first circuit layer.

In some embodiments of the present disclosure, the base layer and the build-up material layer completely surround the first circuit layer.

In some embodiments of the present disclosure, a manufacturing method of a circuit board structure is provided. The manufacturing method includes the following steps. A base layer is provided. A first circuit layer is disposed on the base layer. A support material layer is disposed on the base layer, wherein the support material layer is located on one side of the first circuit layer. A build-up material layer is disposed on the first circuit layer and the support material layer. A second circuit layer is disposed on the build-up material layer.

In some embodiments of the present disclosure, the step of forming the support material layer includes the following steps. A support material is coated on the base layer. A prebaking process and a baking process is performed to form the support material into the support material layer.

In some embodiments of the present disclosure, the support material is not in direct contact with the first circuit layer.

In some embodiments of the present disclosure, the shortest distance between the support material and the first circuit layer is greater than 0.03 mm.

In some embodiments of the present disclosure, the base layer includes a first region and a second region, and the ratio of the area of the first circuit layer located on the first region to the total area of the first region is less than the ratio of the area of the first circuit layer located on the second region to the total area of the second region, wherein the support material layer is located at least in the first region.

In some embodiments of the present disclosure, the ratio of the area of the first circuit layer located on the first region to the total area of the first region is less than 50%.

In some embodiments of the present disclosure, the upper surface of the build-up material layer located on the support material layer and the upper surface of the build-up material layer located on the first circuit layer are coplanar.

In some embodiments of the present disclosure, the material of the support material layer includes epoxy, silicon dioxide, bisphenol F, epichlorhydrin, a copolymer thereof, or a combination thereof.

The circuit board structure of the present disclosure can be applied in a variety of electrical devices. In order to make the features and advantages of the present disclosure more comprehensible, various embodiments are specially cited below, together with the accompanying drawings, to be described in detail as follows.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIGS. 1 to 8 are respectively schematic cross-sectional views showing the circuit board structure at different stages of the manufacturing process according to some embodiments of the present disclosure.

FIGS. 9 to 11 are respectively schematic cross-sectional views showing the circuit board structure at different stages in subsequent processes according to other embodiments of the present disclosure.

### DETAILED DESCRIPTION OF THE INVENTION

The devices of various embodiments of the present disclosure will be described in detail hereinafter. It should be understood that the following description provides many different embodiments for implementing various aspects of some embodiments of the present disclosure. The specific elements and arrangements described hereinafter are merely to clearly describe some embodiments of the present disclosure. Of course, these are only used as examples rather than limitations of the present disclosure. Furthermore, similar or corresponding reference numerals may be used in different embodiments to designate similar or corresponding elements in order to clearly describe the present disclosure. However, the use of these similar or corresponding reference numerals is only for the purpose of simply and clearly description of some embodiments of the present disclosure, and does not imply any correlation between the different embodiments or structures discussed.

In addition, it should be understood that ordinal numbers such as “first”, “second”, and the like used in the description and claims are used to modify elements and are not intended to imply and represent the element(s) have any previous ordinal numbers, and do not represent the order of a certain element and another element, or the order of the manufacturing method, and the use of these ordinal numbers is only used to clearly distinguished an element with a certain name and another element with the same name. The claims and the specification may not use the same terms, for example, a first element in the specification may be a second element in the claim.

In some embodiments of the present disclosure, terms related to bonding and connection, such as “connect”, “interconnect”, “bond”, and the like, unless otherwise defined, may refer to two structures in direct contact, or may also refer to two structures not in direct contact, that is there is another structure disposed between the two structures. Moreover, the terms related to bonding and connection can also include embodiments in which both structures are movable, or both structures are fixed. Furthermore, the terms “electrically connected” or “electrically coupled” include any direct and indirect means of electrical connection.

Herein, the terms “approximately”, “about”, and “substantially” generally mean within 10%, within 5%, within 3%, within 2%, within 1%, or within 0.5% of a given value or range. The given value is an approximate value, that is, “approximately”, “about”, and “substantially” can still be implied without the specific description of “approximately”, “about”, and “substantially”. The phrase “a range between a first value and a second value” means that the range includes the first value, the second value, and other values in between. Furthermore, any two values or directions used for comparison may have certain tolerance. If the first value is equal to the second value, it implies that there may be a tolerance within about 10%, within 5%, within 3%, within 2%, within 1%, or within 0.5% between the first value and the second value. If the first direction is perpendicular to the second direction, the angle between the first direction and the second direction may be between 80 degrees and 100 degrees. If the first direction is parallel to the second direction, the angle between the first direction and the second direction may be between 0 degrees and 10 degrees.

It should be understood that, in the following embodiments, features in several different embodiments may be replaced, recombined, and bonded to complete other embodiments without departing from the spirit of the present disclosure. The features of the various embodiments can be used in any combination as long as they do not violate the spirit of the present disclosure or conflict with each other.

Unless otherwise defined, all terms (including technical and scientific terms) used herein have the same meaning as commonly understood by a person of ordinary skills in the art. It is understood that these terms, such as those defined in commonly used dictionaries, should be interpreted as having meanings consistent with the relevant art and the background or context of the present disclosure, and should not be interpreted in an idealized or overly formal manner, unless otherwise defined in the embodiments of the present disclosure.

In the manufacturing process of existing circuit board structures, a build-up process such as a thermal lamination process is used to provide a build-up material layer on the base layer (or core layer). However, the density of circuit patterns in different regions on the base layer may be different depending on design requirements. For example, the density of circuit patterns may range from 10% to 90%. In this case, it may be difficult for the build-up material layer to be blanketly disposed on the base layer and the circuit pattern. For example, the height of the build-up material layer in a region with a low density of circuit patterns may be slightly less than the height of the build-up material layer in a region with a high density of circuit patterns. For high-frequency applications, differences in height may significantly affect impedance matching and signal integrity. As a result, the electrical characteristics of the circuit board structures may not meet the usage requirements. To this end, the present disclosure provides a circuit board structure that effectively solves the problem of uneven height of the circuit board structure by disposing a support material layer between the build-up material layer and the base layer.

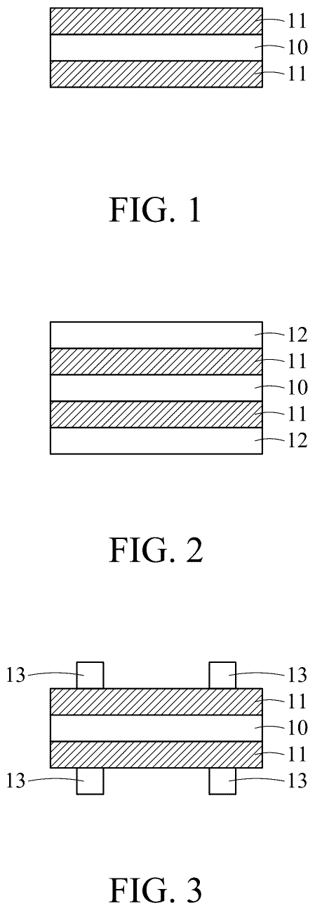

FIGS. 1 to 8 are schematic cross-sectional views the showing circuit board structure at different stages of the manufacturing process according to some embodiments of the present disclosure. It should be noted that, for the sake of simplicity and ease of understanding, the drawings of the present disclosure may exaggerate the sizes of components and their proportions (for example, the base layer 10, the first circuit layer 14, the support material layer 15, the build-up material layer 16, and the second circuit layer 17 that will be described hereinafter). In addition, the drawings of the present disclosure may omit some components in the circuit board structure, but a person having ordinary skill in the art can understand that the circuit board structure may also include other common components.

As shown in FIG. 1, a base substrate is provided, wherein the base substrate includes the base layer 10 and the conductive material 11. Specifically, the base layer 10 is used to carry components disposed thereon during the manufacturing process (for example, the first circuit layer 14 and the support material layer 15 mentioned below, etc.). In some embodiments, the material of the base layer 10 may be a prepreg that contains a polymer material, a fiber material, or other suitable materials, but the present disclosure is not limited thereto. For example, the polymer material may be or may include epoxy, polyimide (PI), polypropylene (PP), other suitable polymer materials, or a combination thereof, but the present disclosure is not limited thereto. For example, the fiber material may include carbon fiber, glass fiber, other suitable fiber materials, or a combination thereof, but the present disclosure is not limited thereto.

As shown in FIG. 1, the conductive material 11 is disposed on one side or both sides of the base layer 10. Specifically, the conductive material 11 is used to be patterned in subsequent processes to form the first circuit layer 14. In some embodiments, the conductive material 11 may be or may include conductive material. For example, the conductive material may be aluminum (Al), copper (Cu), an alloy or a compound thereof, but the present disclosure is not limited thereto. In some embodiments, the conductive material 11 may be copper foil. For example, the copper foil may be or include brass, phosphor bronze, beryllium alloy, or oxygen-free copper, but the present disclosure is not limited thereto.

As shown in FIG. 2, following the above steps, the mask material 12 is disposed on the conductive material 11. Specifically, the mask material 12 is used to be patterned in subsequent processes to form the patterned mask 13. In some embodiments, the mask material 12 may be or include a hard mask, a soft mask, or a combination thereof. For example, the mask material 12 may be or include silicon oxide, silicon nitride, silicon carbide, silicon oxycarbide, photoresist, others suitable materials, or a combination thereof, but the present disclosure is not limited thereto. In this embodiment, the masking material 12 is photoresist. As shown in FIG. 3, following the above steps, the mask material 12 is patterned to form the patterned mask 13. Specifically, the patterned mask 13 is used to pattern the conductive material 11 in subsequent processes to form the first circuit layer 14 on the base layer 10.

In some embodiments, the steps shown in FIGS. 2 to 3 may be performed by lithography to pattern the mask material 12 to form the patterned mask 13. For example, the lithography process may include photoresist coating (e.g., spin-on coating, lamination), soft baking, mask aligning, exposure, post-exposure baking, photoresist developing, rinsing, drying (e.g., spin-drying and/or hard baking), other suitable lithography techniques, and/or a combination thereof.

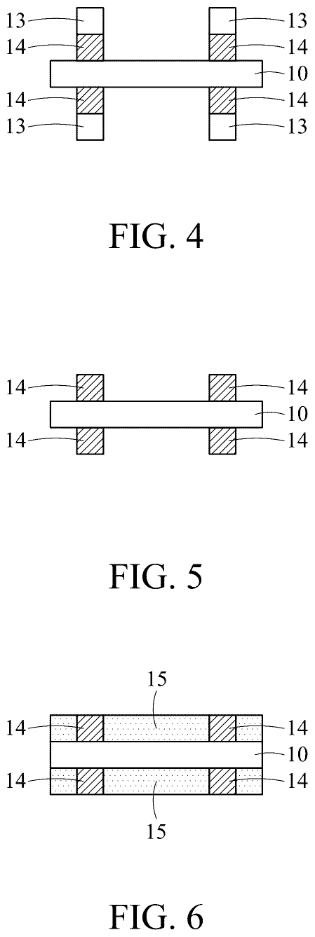

As shown in FIG. 4, following the above steps, the conductive material 11 is patterned to form the first circuit layer 14. Specifically, the first circuit layer 14 is used to transmit signals, such as control signals, image signals, sound signals, other suitable signals, or a combination thereof, but the present disclosure is not limited thereto. In some embodiments, the conductive material 11 may be patterned by dry etching, wet etching, or a combination thereof, but the present disclosure is not limited thereto.

In some embodiments, according to design requirements, the circuit density of the first circuit layer 14 located on different regions of the base layer 10 may be different. For example, the base layer 10 may have a first region and a second region. Among them, the circuit density of the first circuit layer 14 located on the first region may be less than the circuit density of the first circuit layer 14 located on the second region. In other words, the ratio of the area of the first circuit layer 14 located on the first region to the total area of the first region is less than the ratio of the area of the first circuit layer 14 located on the second region to the total area of the second region. It should be noted that in some embodiments where the first circuit layer 14 includes copper, the above ratio may be called the residual copper rate, that is, the ratio of the remaining lines to the unit area, wherein the lines are the copper foil after being etched. For example, the residual copper rate in the first region may be between 5% and 50%, and the residual copper rate in the second region may be between 50% and 95%. In this case, the circuit density (i.e., the residual copper rate) of the first region is low, and the circuit density (i.e., the residual copper rate) of the second region is high. It should be noted that the first region and the second region may be located on the same side of the base layer 10, or may be located on different sides of the base layer.

As shown in FIG. 5, following the above steps, the patterned mask 13 is removed to expose the first circuit layer 14. In some embodiments, the patterned mask 13 may be removed by dry etching, wet etching, or a combination thereof, but the present disclosure is not limited thereto.

As shown in FIG. 6, the support material layer 15 is formed on the base layer 10, wherein the support material layer 15 is located on one side or both sides of the first circuit layer 14. Specifically, the support material layer 15 is used to support and carry the build-up material layer 16 in subsequent processes. In some embodiments, the step of forming the support material layer 15 includes the following steps. A support material is coated on the base layer 10. A pre-baking process is performed to pre-cure the support material. A baking process is performed to form the pre-cured support material into the support material layer 15.

In some embodiments, the support material may be or may include epoxy, silica, bisphenol F, epichlorhydrin, other suitable materials, a copolymer thereof, or a combination thereof, but the present disclosure is not limited thereto.

In some embodiments, the temperature of the pre-baking process may be between 90° C. and 130° C., and the time of the pre-baking process may be between 40 min and 60 min, but the present disclosure is not limited thereto. For example, the temperature of the pre-baking process may be 90° C., 100° C., 110° C., 120° C., 130° C., or any value or range between the above values, and the time of the pre-baking process may be between 40 min, 45 min, 50 min, 55 min, 60 min, or any value or range between the above values.

In some embodiments, the temperature of the baking process may be between 90° C. and 130° C., and the time of the baking process may be between 40 min and 60 min, but the present disclosure is not limited thereto. For example, the temperature of the baking process may be 90° C., 100° C., 110° C., 120° C., 130° C., or any value or range between the above values, and the time of the baking process may be between 40 min, 45 min, 50 min, 55 min, 60 min, or any value or range between the above values.

It should be noted that the above process is only an example and is not intended to limit the present disclosure. A person having ordinary skill in the art may select similar or completely different processes depending on the specific type of the support material layer 15.

In some embodiments, the support material layer 15 is at least disposed on a region with a lower circuit density (for example, residual copper rate) to prevent the subsequent build-up material layer 16 from collapsing or recessing in this region, resulting in uneven height. For example, when the ratio of the area of the first circuit layer 14 located on the first region to the total area of the first region is less than 50%, such as 45%, 40%, 35%, 30%, 25%, 20%, or any value or range between the above values, the support material layer 15 may be disposed in the first region to prevent the build-up material layer 16 from collapsing or recessing. In addition, when the ratio of the area of the first circuit layer 14 located on the second region to the total area of the second region is higher than 50%, such as 55%, 60%, 65%, 70%, 75%, 80%, or any value or range between the above values, the step of providing the support material layer 15 in the second region may be omitted. However, the present disclosure is not limited thereto. In some embodiments, the support material layer 15 may also be disposed on the entire base layer 10 and cover the surface of the base layer 10 that is not covered by the first circuit layer 14. That is, the support material layer 15 may be disposed in the first region and the second region at the same time.

In some embodiments, the upper surface of the first circuit layer 14 is coplanar with the upper surface of the support material layer 15. In other words, the support material layer 15 may be filled on the base layer 10 and coplanar with the first circuit layer 14. However, the present disclosure is not limited thereto. In other embodiments, the upper surface of the first circuit layer 14 and the upper surface of the support material layer 15 may be not coplanar. Specifically, under the condition that the build-up material layer 16 may blanketly cover the first circuit layer 14, the specific thickness, shape, or placement position of the support material layer 15 may be within a specific range to improve process margin (for example, it may have a relatively great thickness or great tolerance). In some embodiments, the thickness of the support material layer 15 is between 0.01 mm and 0.12 mm, but the present disclosure is not limited thereto. For example, the thickness of the support material layer 15 may be 0.01 mm, 0.04 mm, 0.06 mm, 0.08 mm, 0.1 mm, 0.12 mm, or any value or range between the above values.

In some embodiments, the material of the support material layer 15 includes epoxy, silicon dioxide, bisphenol F, epichlorohydrin, other suitable materials, a copolymer thereof, or combinations thereof. Among them, the material of the support material layer 15 may be selected according to electrical requirements. For example, a specific material may be selected based on permittivity (Dk) (or relative permittivity), damping factor (Df) (or internal dissipation, loss tangent), but the present disclosure is not limited thereto. In some embodiments, the material of the support material layer 15 may also be selected based on other physical or chemical properties. For example, the material of support material layer 15 may be selected based on mechanical strength, viscosity, glass transition temperature, chemical stability, corrosion resistance, other suitable properties, or a combination thereof.

In some embodiments, the support material layer 15 may be in direct contact with the first circuit layer 14 according to design requirements. For example, when the support material layer 15 includes epoxy, silicon dioxide, bisphenol F, epichlorohydrin, a copolymer thereof, or a combination thereof, the support material layer 15 has a better impedance matching with other layers. In this case, the support material layer 15 may be in direct contact with the first circuit layer 14, as shown in FIG. 6. However, the present disclosure is not limited thereto. In other embodiments, the support material layer 15 may be not in direct contact with the first circuit layer 14, and the detailed description may be referred to hereinafter.

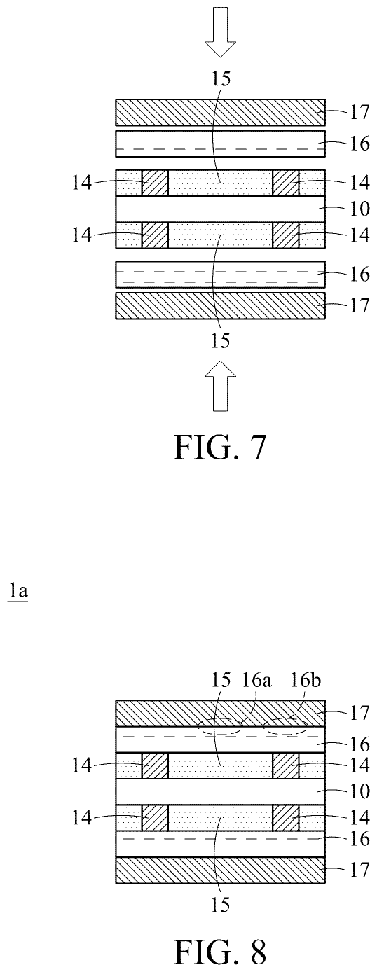

As shown in FIGS. 7 and 8, following the above steps, the build-up material layer 16 is formed on the first circuit layer 14 and the support material layer 15. Specifically, the build-up material layer 16 is used to carry the second circuit layer 17 that is disposed subsequently. In some embodiments, the build-up material layer 16 may be formed by a lamination process, a coating process, other suitable processes, or a combination thereof, but the present disclosure is not limited thereto. It should be noted that in the present disclosure, since the support material layer 15 is disposed, the build-up material layer 16 has a substantially flat upper surface. Specifically, the upper surface 16a of the build-up material layer 16 located on the support material layer 15 is coplanar with the upper surface 16b of the build-up material layer 16 located on the first circuit layer 14. In other words, the build-up material layer 16 may be blanketly disposed without collapse or recess.

In some embodiments, the build-up material layer 16 may include multiple sub-layers, and similar or identical processes or materials may be used to form each sub-layer. In some embodiments, the material of the build-up material layer 16 may be or may include epoxy, polyimide, build-up material (Ajinomoto buildup film, ABF), other suitable polymer materials, or a combination thereof, but the present disclosure is not limited thereto. In some embodiments, the material of the support material layer 15 is the same as the material of the build-up material layer 16, but the present disclosure is not limited thereto.

As shown in FIGS. 7 and 8, following the above steps, the second circuit layer 17 is disposed on the build-up material layer 16. In some embodiments, the second circuit layer 17 may be or may include a conductive material. For example, the conductive material may be aluminum, copper, an alloy or a compound thereof, but the present disclosure is not limited thereto. In some embodiments, the second circuit layer 17 may be copper foil. For example, the copper foil may be or include brass, phosphor bronze, beryllium copper, or oxygen-free copper, but the present disclosure is not limited thereto. In some embodiments, the second circuit layer 17 may also be patterned through a lithography process, but the present disclosure is not limited thereto.

As mentioned above, the present disclosure provides the circuit board structure, which includes the base layer 10, the first circuit layer 14, the support material layer 15, the build-up material layer 16, and the second circuit layer 17. The first circuit layer 14 is disposed on the base layer 10. The support material layer 15 is disposed on the base layer 10 and located on one side of the first circuit layer 14. The build-up material layer 16 is disposed on the first circuit layer 14 and the support material layer 15. The second circuit layer 17 is disposed on the build-up material layer 16. Among them, by providing the support material layer 15, the build-up material layer 16 may be blanketly disposed on the first circuit layer 14, thereby avoiding the problems of collapse and recess. As the result, the circuit board structure of the present disclosure has better impedance matching and signal stability, thereby being able to solve some problems of the existing technology and be applied in electronic products with higher requirements.

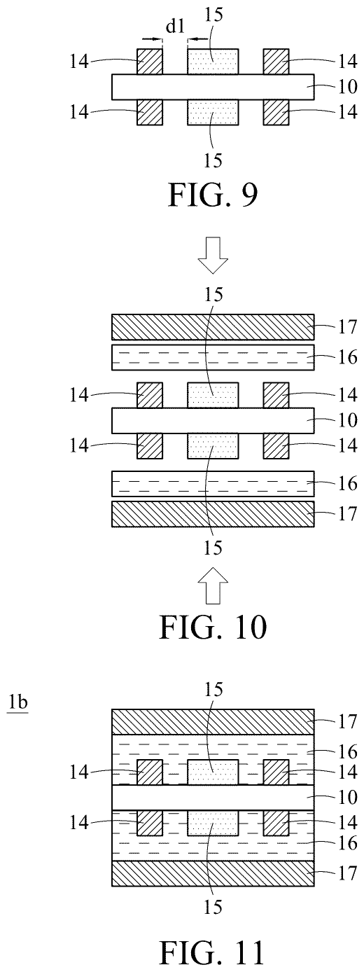

FIGS. 9 to 11 are schematic cross-sectional views showing the circuit board structure at different stages in the manufacturing process according to other embodiments of the present disclosure. Among them, FIG. 9 shows a continuation step of the steps of FIG. 5. Therefore, the steps of FIG. 5 and before FIG. 5 may be referred to the above, and the descriptions are omitted. As shown in FIG. 9, following the steps of FIG. 5, the support material layer 15 is formed on the base layer 10, wherein the support material layer 15 is located on one side or both sides of the first circuit layer 14, and the support material layer 15 is not in direct contact with the first circuit layer 14. Specifically, the shortest distance d between the support material layer 15 and the first circuit layer 14 is greater than 0.03 mm, but the present disclosure is not limited thereto. For example, even when the support material layer 15 includes the above-mentioned materials or other suitable materials, the shortest distance d between the support material layer 15 and the first circuit layer 14 may still be 0.03 mm. By preventing the support material layer 15 from being in direct contact with the first circuit layer 14, the impedance matching and signal integrity may be further adjusted to meet different electrical requirements.

In some embodiments, a process similar to the above-mentioned embodiment may be used, and the support material layer 15 is disposed on the entire base layer 10 through a coating process, a pre-baking process, and a baking process, and then the support material layer 15 adjacent the first circuit layer 14 is removed through an etching process. However, the present disclosure is not limited thereto. In other embodiments, the support material may also be selectively coated at a position away from the first circuit layer 14 to dispose the support material layer 15 through a pre-baking process and a baking process, thereby omitting the etching process.

As shown in FIGS. 10 and 11, following the above steps, the build-up material layer 16 is formed on the first circuit layer 14 and the support material layer 15. It should be noted that since the first circuit layer 14 and the support material layer 15 do not completely cover the base layer 10, the build-up material layer 16 may cover the exposed surface of the base layer 10 and cover the first circuit layer 14 from the side of first circuit layer 14. In other words, the build-up material layer 16 is located between the support material layer 15 and the first circuit layer 14, and the base layer 10 and the build-up material layer 16 completely surround the first circuit layer 14. In this way, impedance matching and signal integrity may be effectively controlled.

In this embodiment, the circuit board structure is provided, which includes the base layer 10, the first circuit layer 14, the support material layer 15, the build-up material layer 16, and the second circuit layer 17. The first circuit layer 14 is disposed on the base layer 10. Among them, by separating the support material layer 15 and the first circuit layer 14 from each other, the impedance matching and signal stability of the circuit board structure may be further improved.

In summary, the present disclosure provides a circuit board structure that effectively improves the problem of uneven thickness of the circuit board structure by disposing a support material layer between the build-up material layer and the base layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A circuit board structure, comprising:
a base layer;
a first circuit layer disposed on the base layer;
a support material layer disposed on the base layer and located on one side of the first circuit layer;
a build-up material layer disposed on the first circuit layer and the support material layer; and
a second circuit layer disposed on the build-up material layer.

2. The circuit board structure as claimed in claim 1, wherein the base layer comprises a first region and a second region, and a ratio of an area of the first circuit layer located on the first region to a total area of the first region is less than a ratio of an area of the first circuit layer located on the second region to a total area of the second region, wherein the support material layer is located at least in the first region.

3. The circuit board structure as claimed in claim 2, wherein the ratio of the area of the first circuit layer located on the first region to the total area of the first region is less than 50%.

4. The circuit board structure as claimed in claim 1, wherein an upper surface of the first circuit layer and an upper surface of the support material layer are coplanar.

5. The circuit board structure as claimed in claim 1, wherein an upper surface of the build-up material layer located on the support material layer and an upper surface of the build-up material layer located on the first circuit layer are coplanar.

6. The circuit board structure as claimed in claim 1, wherein a material of the support material layer comprises epoxy, silicon dioxide, bisphenol F, epichlorhydrin, a copolymer thereof, or a combination thereof.

7. The circuit board structure as claimed in claim 1, wherein a material of the support material layer is the same as a material of the build-up material layer.

8. The circuit board structure as claimed in claim 1, wherein a thickness of the support material layer is between 0.01 mm and 0.12 mm.

9. The circuit board structure as claimed in claim 1, wherein the support material layer is not in direct contact with the first circuit layer.

10. The circuit board structure as claimed in claim 9, wherein a shortest distance between the support material layer and the first circuit layer is greater than 0.03 mm.

11. The circuit board structure as claimed in claim 9, wherein the build-up material layer is located between the support material layer and the first circuit layer.

12. The circuit board structure as claimed in claim 11, wherein the base layer and the build-up material layer completely surround the first circuit layer.

13. A manufacturing method of a circuit board structure, comprising:
providing a base layer;
disposing a first circuit layer on the base layer;
disposing a support material layer on the base layer, wherein the support material layer is located on one side of the first circuit layer;
disposing a build-up material layer on the first circuit layer and the support material layer; and
disposing a second circuit layer on the build-up material layer.

14. The manufacturing method of the circuit board structure as claimed in claim 13, wherein the step of forming the support material layer comprises:
coating a support material on the base layer; and
performing a prebaking process and a baking process to form the support material into the support material layer.

15. The manufacturing method of the circuit board structure as claimed in claim 14, wherein the support material is not in direct contact with the first circuit layer.

16. The manufacturing method of the circuit board structure as claimed in claim 15, wherein a shortest distance between the support material and the first circuit layer is greater than 0.03 mm.

17. The manufacturing method of the circuit board structure as claimed in claim 13, wherein the base layer comprises a first region and a second region, and a ratio of an area of the first circuit layer located on the first region to a total area of the first region is less than a ratio of an area of the first circuit layer located on the second region to a total area of the second region, wherein the support material layer is located at least in the first region.

18. The manufacturing method of the circuit board structure as claimed in claim 17, wherein the ratio of the area of the first circuit layer located on the first region to the total area of the first region is less than 50%.

19. The manufacturing method of the circuit board structure as claimed in claim 13, wherein an upper surface of the build-up material layer located on the support material layer and an upper surface of the build-up material layer located on the first circuit layer are coplanar.

20. The manufacturing method of the circuit board structure as claimed in claim 13, wherein a material of the support material layer comprises epoxy, silicon dioxide, bisphenol F, epichlorhydrin, a copolymer thereof, or a combination thereof.
